(19) United States
(12) Patent Application Publication
(10) Pub. No.: US 2026/0369986 A1
(43) Pub. Date: Nov. 19, 2026

(54) PROTECTION CIRCUIT MODULE AND BATTERY ASSEMBLY INCLUDING THE SAME

(71) Applicant: SAMSUNG SDI CO., LTD., Yongin-Si (KR)

(72) Inventor: Harim LEE, Yongin-Si (KR)

(21) Appl. No.: 19/336,297

(22) Filed: Sep. 22, 2025

(30) Foreign Application Priority Data
Apr. 22, 2025 (KR) 10-2025-0052657

(51) Int. Cl. H02H 7/18; H01M 10/42; H01M 50/519; H01M 50/524; H05K 1/14

(52) U.S. Cl. CPC H02H 7/18; H01M 10/425; H01M 50/519; H01M 50/524; H05K 1/144; H05K 2201/041

(57) ABSTRACT

A protection circuit module includes: a first circuit board electrically connected to a battery cell, and extending in a first direction; a second circuit board electrically connected to the first circuit board; and a coupling member coupling the first circuit board and the second circuit board to each other. The first circuit board includes an indented part at an end overlapping with the second circuit board in a second direction crossing the first direction, and at least a portion of the coupling member is inserted into the indented part.

### CROSS-REFERENCE TO RELATED APPLICATION

The present application claims priority to and the benefit of Korean Patent Application No. 10-2025-0052657, filed on Apr. 22, 2025, in the Korean Intellectual Property Office, the entire disclosure of which is incorporated by reference herein.

### BACKGROUND

### 1. Field

Aspects of embodiments of the present disclosure relate to a protection circuit module, and a battery assembly including the protection circuit module.

### 2. Description of the Related Art

A secondary battery is a rechargeable and dischargeable battery, unlike a primary battery which is not rechargeable. Low-capacity secondary batteries are used in portable small electronic devices such as smartphones, feature phones, laptop computers, digital cameras, and camcorders, and large-capacity secondary batteries are widely used as power sources for driving motors in hybrid vehicles and electric vehicles, and as batteries for power storage. Such a secondary battery includes an electrode assembly composed of a positive electrode and a negative electrode, a case for accommodating the electrode assembly, and electrode terminals connected to the electrode assembly.

A secondary battery may be provided with a protection circuit module (PCM) to protect the battery from overcharging, overdischarging, or overcurrent. The protection circuit module may prevent the battery from igniting or exploding by interrupting a current flow when the internal temperature or voltage of the battery rises.

The above information disclosed in this Background section is for enhancement of understanding of the background of the present disclosure, and therefore, it may contain information that does not constitute related (or prior) art.

### SUMMARY

A protection circuit module (PCM) may include a plurality of circuit boards. The plurality of circuit boards may be coupled to each other and electrically connected to each other. During a process of inspecting the protection circuit module or installing the secondary battery, an external force may be applied to a coupled part of the plurality of circuit boards. In this case, the coupled part of the plurality of circuit boards may be damaged or fractured by the external force. As such, an improvement to a coupling strength between the plurality of circuit boards may be desired.

Embodiments of the present disclosure may be directed to a protection circuit module, and a battery assembly including the protection circuit module.

However, the technical problem to be solved by the present disclosure is not limited to the above problem, and other problems not mentioned herein, and aspects and features of the present disclosure that would address such problems, will be clearly understood by those skilled in the art from the description of the present disclosure below.

According to one or more embodiments of the present disclosure, a protection circuit module includes: a first circuit board electrically connected to a battery cell, and extending in a first direction; a second circuit board electrically connected to the first circuit board; and a coupling member coupling the first circuit board and the second circuit board to each other. The first circuit board includes an indented part at an end overlapping with the second circuit board in a second direction crossing the first direction, and at least a portion of the coupling member is inserted into the indented part.

In an embodiment, the indented part may have a concave shape in an inner direction of the first circuit board on a surface of the end facing the first direction.

In an embodiment, the indented part may penetrate the end of the first circuit board in the second direction.

In an embodiment, the indented part may be located at a center of the first circuit board with respect to a third direction crossing the first direction and the second direction.

In an embodiment, a length of the indented part may be less than or equal to 50% of a width of the first circuit board with respect to a third direction crossing the first direction and the second direction.

In an embodiment, a length of the indented part may be less than or equal to 50% of a width of the first circuit board with respect to the first direction.

In an embodiment, the coupling member may have a width that decreases as a distance from the end increases, and a maximum width of the coupling member may be greater than or equal to a width of the indented part.

In an embodiment, the indented part may penetrate the end of the first circuit board in a third direction crossing the first direction and the second direction.

In an embodiment, the indented part may be located at a center of the first circuit board with respect to the second direction.

In an embodiment, a length of the indented part may be less than or equal to 50% of a thickness of the first circuit board with respect to the second direction.

In an embodiment, a length of the indented part may be less than or equal to 50% of a thickness of the first circuit board with respect to the first direction.

In an embodiment, the coupling member may have a thickness that decreases as a distance from the end increases, and a top end of the coupling member may be higher than or at a same height as that of a top end of the indented part.

In an embodiment, the coupling member may include at least one of an epoxy resin, silicone, polyurethane, or acrylic.

In an embodiment, a width of the second circuit board may correspond to a width of the first circuit board.

In an embodiment, a center of the second circuit board may correspond to a center of the first circuit board with respect to a third direction crossing the first direction and the second direction.

According to one or more embodiments of the present disclosure, a battery assembly includes: a battery cell including an electrode tab; and a protection circuit module electrically connected to the electrode tab. The protection circuit module includes: a first circuit board electrically connected to the battery cell, and extending in a first direction; a second circuit board electrically connected to the first circuit board; and a coupling member coupling the first circuit board and the second circuit board to each other. The first circuit board includes an indented part at an end overlapping with the second circuit board in a second direction crossing the first direction, and at least a portion of the coupling member is inserted into the indented part.

In an embodiment, the indented part may have a concave shape in an inner direction of the first circuit board on a surface of the end facing the first direction.

In an embodiment, the indented part may penetrate the end of the first circuit board in the second direction.

In an embodiment, the indented part may penetrate the end of the first circuit board in a third direction crossing the second direction.

In an embodiment, the coupling member may include at least one of an epoxy resin, silicone, polyurethane, or acrylic.

According to some embodiments of the present disclosure, a protection circuit module having an improved mechanical strength, and a battery assembly including the protection circuit module may be provided.

According to some embodiments of the present disclosure, a protection circuit module having an improved coupling strength between a plurality of circuit boards, and a battery assembly including the protection circuit module may be provided.

According to some embodiments of the present disclosure, the coupling strength between a plurality of circuit boards may be improved by arranging a coupling member in an indented part formed in a circuit board to couple the plurality of circuit boards to each other.

According to some embodiments of the present disclosure, the coupling member may absorb an external force applied to the protection circuit module to prevent or substantially prevent damage to the coupling part of the plurality of circuit boards, and the protection circuit module may operate more stably due to a high heat resistance of the coupling member in a high-temperature state.

However, aspects and features of the present disclosure are not limited to those described above, and other aspects and features not mentioned will be clearly understood by a person skilled in the art from the detailed description, described below.

The above, and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The following drawings attached to the present specification illustrate embodiments of the present disclosure, and further describe aspects and features of the present disclosure together with the detailed description of the present disclosure. Thus, the present disclosure should not be construed as being limited to the drawings.

FIG. 1 is an exploded perspective view illustrating an example of a battery assembly according to an embodiment of the present disclosure.

FIG. 2 is a plan view illustrating an example of a battery assembly according to an embodiment of the present disclosure.

FIG. 3 is a plan view illustrating an example of a protection circuit module according to an embodiment of the present disclosure.

FIG. 4 is a plan view illustrating an example of a protection circuit module including an indented part penetrating an end in a second direction, and a coupling member having a width corresponding to a width of the indented part, according to an embodiment of the present disclosure.

FIG. 5 is a plan view illustrating an example of a protection circuit module including an indented part penetrating an end in a second direction, and a coupling member having a width greater than a width of the indented part, according to an embodiment of the present disclosure.

FIG. 6 is a plan view illustrating an example of a protection circuit module including an indented part penetrating an end in a second direction, and an end including a curved surface at a corner, according to an embodiment of the present disclosure.

FIG. 7 is a side view illustrating an example of a protection circuit module including an indented part penetrating an end in a second direction, according to an embodiment of the present disclosure.

FIG. 8 is a plan view illustrating an example of a protection circuit module including an indented part penetrating an end with respect to a third direction, according to an embodiment of the present disclosure.

FIG. 9 is a side view illustrating an example of a protection circuit module including an indented part penetrating an end with respect to a third direction, and a coupling member having a top end higher than a top end of the indented part, according to an embodiment of the present disclosure.

FIG. 10 is a side view illustrating an example of a protection circuit module including an indented part penetrating an end with respect to a third direction, and a coupling member having a top end corresponding to a top end of the indented part, according to an embodiment of the present disclosure.

FIG. 11 is a side view illustrating an example of a protection circuit module including an indented part penetrating an end with respect to a third direction, and a coupling member having a top end corresponding to a top end of the indented part, according to an embodiment of the present disclosure.

### DETAILED DESCRIPTION

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some of the embodiments of the present disclosure and do not represent all of the technical spirit, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terms used in the present specification are for describing embodiments of the present disclosure and are not intended to limit the present disclosure.

In the drawings, the sizes and relative sizes of the layers and regions shown may be exaggerated for convenience of illustration. That is, the present disclosure is not limited to the sizes shown in the drawings. In addition, throughout the specification, the same reference numerals refer to the same components. Hereinafter, the meaning of ‘corresponds to’ may mean identical to or substantially identical to within a suitable error range.

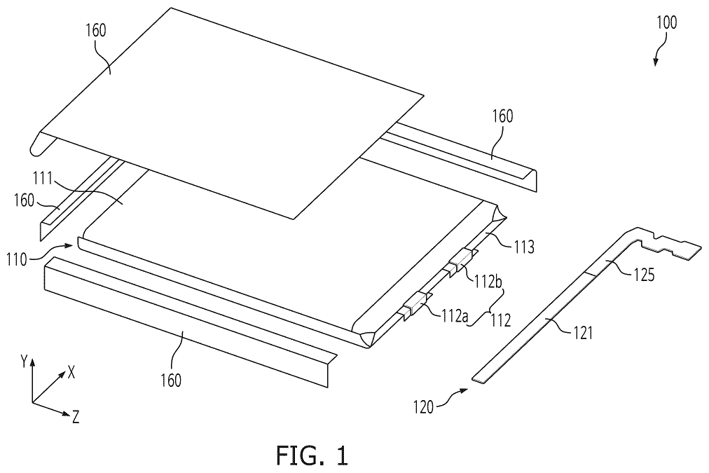

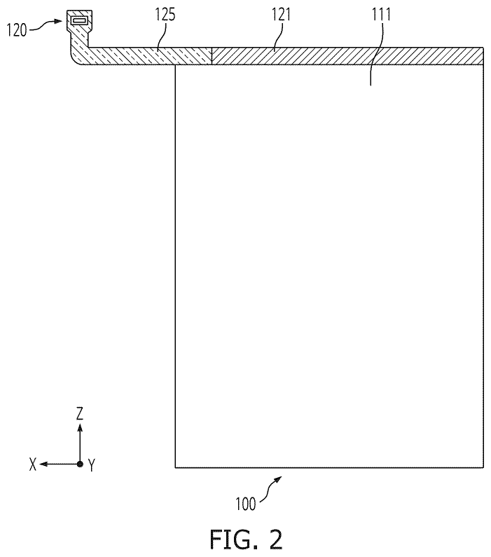

FIG. 1 is an exploded perspective view illustrating an example of a battery assembly according to an embodiment of the present disclosure. FIG. 2 is a plan view illustrating an example of a battery assembly according to an embodiment of the present disclosure.

Referring to FIG. 1 and FIG. 2, a battery assembly 100 may include a battery cell 110, a protection circuit module 120 electrically connected to the battery cell 110, a fixing tape for fixing the protection circuit module 120 to the battery cell 110, and a cover tape 160 covering a surface of the battery cell 110.

The battery cell 110 may include an electrode assembly, and an exterior material 111 enclosing a surface of the electrode assembly. The electrode assembly may include a positive electrode plate, a negative electrode plate, and a separator interposed between the positive electrode plate and the negative electrode plate. An electrode tab 112 may protrude from one side of the electrode assembly. For example, a positive electrode tab 112a connected to the positive electrode plate may protrude, and a negative electrode tab 112b connected to the negative electrode plate may protrude. The exterior material 111 may enclose the surface of the electrode assembly, such that the electrode tab 112 is exposed to the outside.

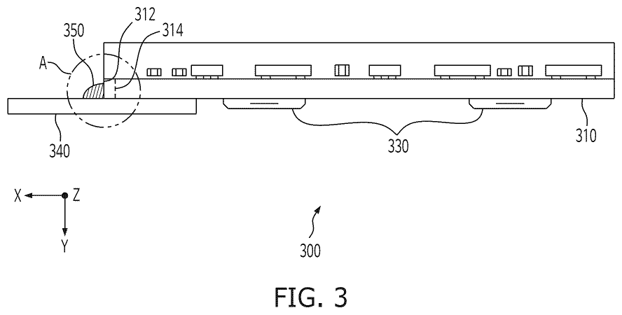

The protection circuit module 120 may prevent an overcharge, an overdischarge, and/or an overcurrent of the battery cell 110. The protection circuit module 120 may include a first circuit board 121, a second circuit board 125, and a coupling member. The coupling member may couple the first circuit board 121 and the second circuit board 125 to each other, as will be described in more detail below with reference to FIGS. 3 to 10.

Electronic components for monitoring and protecting the state of the battery cell 110 may be mounted on the first circuit board 121. For example, electronic components, such as a relay, a capacitor, and a PTC (Positive Temperature Coefficient) thermistor may be mounted on one surface the first circuit board 121.

The first circuit board 121 may be electrically connected to the battery cell 110. For example, the first circuit board 121 may be electrically connected to the electrode tab 112 protruding from one side of the battery cell 110 through an electrode terminal. In this case, the electrode terminal connected to the positive electrode tab 112a may function as a positive electrode terminal, and the electrode terminal connected to the negative electrode tab 112b may function as a negative electrode terminal.

The second circuit board 125 may be electrically connected to the first circuit board 121. For example, the second circuit board 125 may be on the other surface of the first circuit board 121 opposite to the one surface of the first circuit board 121 on which the electronic components are mounted. The second circuit board 125 may be electrically connected to the first circuit board 121 by various suitable methods, such as soldering or blazing.

The second circuit board 125 may be a detachable circuit board. For example, the second circuit board 125 may be manufactured in a state separated from the first circuit board 121, and then may be connected to the first circuit board 121 in an assembly process of the protection circuit module 120. For example, the second circuit board 125, which may be designed differently depending on the kind of battery assembly 100, may be connected to the first circuit board 121.

In an embodiment, the second circuit board 125 may correspond to a Flexible Printed Circuit Board (FPCB). In this case, the second circuit board 125 may be designed in various suitable forms, and thus, may have a higher degree of freedom in design compared to a circuit board composed of a rigid material. A hardness of the second circuit board 125 may be lower than that of the first circuit board 121. For example, the second circuit board 125 may be an FPCB, and the first circuit board 121 may be a PCB. An end of the second circuit board 125 may include a connector for connection with an external device.

The first circuit board 121 and the second circuit board 125 may be multilayered printed circuit boards. In some embodiments, each of the first circuit board 121 and the second circuit board 125 may be made of at least one material selected from a phenolic resin, an epoxy resin, and/or polyimide. For example, each of a plurality of base layers forming a substrate base may include at least one material selected from FR4 (Frame Retardant 4), a tetrafunctional epoxy, polyphenylene ether, an epoxy/polyphenylene oxide, BT (Bismaleimidetriazine), Thermount, cyanate ester, polyimide, and/or a liquid crystal polymer.

The protection circuit module 120 connected to the battery cell 110 may be mounted on one side of the battery cell 110. A terrace part 113 may be formed on one side of the exterior material 111 (e.g., in the direction where the electrode tab 112 protrudes), and the terrace part 113 may provide a space for the protection circuit module 120 to be mounted. For example, an insulating tape may be placed on the terrace part 113, and the protection circuit module 120 may be mounted on the insulating tape.

FIG. 3 is a plan view illustrating an example of a protection circuit module according to an embodiment of the present disclosure.

A protection circuit module 300 shown in FIG. 3 may correspond to the protection circuit module 120 shown in FIG. 1 and FIG. 2 when viewed in the Z-axis direction. An indented part 314 in FIG. 3 is indicated by a dotted line to show a position of the indented part 314.

Referring to FIG. 3, the protection circuit module 300 may include a first circuit board 310, a second circuit board 340, and a coupling member 350. The first circuit board 310 may be electrically connected to the battery cell, and may have a suitable shape extending in a first direction (e.g., the X-axis direction). The second circuit board 340 may be electrically connected to the first circuit board 310. The coupling member 350 may couple the first circuit board 310 and the second circuit board 340 to each other. For example, the coupling member 350 may physically couple the first circuit board 310 and the second circuit board 340 to each other using an adhesive force.

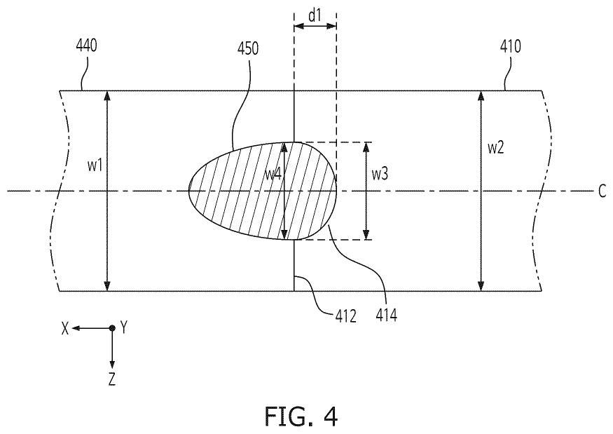

The first circuit board 310 may include the indented part 314 formed at an end 312 overlapping with the second circuit board 340 in a second direction (e.g., the Y-axis direction) perpendicular to or substantially perpendicular to the first direction (e.g., the X-axis direction). According to an embodiment, the indented part 314 may be formed concavely inward of the first circuit board 310 on a surface of the end 312 facing the first direction (e.g., the X-axis direction). According to an embodiment, the indented part 314 may be formed to penetrate the end 312 of the first circuit board in the second direction (e.g., the Y-axis direction). According to an embodiment, the indented part 314 may be formed to penetrate the end 312 of the first circuit board in a third direction (e.g., the Z-axis direction) perpendicular to or substantially perpendicular to the first direction (e.g., the X-axis direction) and the second direction (e.g., the Y-axis direction). The shape of the indented part 314 may be a semicircle, but the present disclosure is not limited thereto, and the indented part 314 may have various suitable shapes, such as an oval or a polygon. This will be described in more detail below with reference to FIGS. 4 to 10.

The first circuit board 310 may include a tab connection part 330. The tab connection part 330 may be on the other surface of the first circuit board 310 opposite to the one surface of the first circuit board 310 on which the electronic components are mounted. The tab connection part 330 may be connected to the electrode tab of the battery cell, and may be electrically connected to the electrode assembly connected to the electrode tab. The tab connection part 330 may be a conductor through which a current for an electrical connection may flow. For example, the tab connection part 330 may include a nickel (Ni) material. The connection between the tab connection part 330 and the electrode tab may be made by soldering, resistance welding, laser welding, or projection welding.

The electronic components may be mounted on the one surface of the first circuit board 310. According to an embodiment, the electronic components as described above may include a protection IC, a FET, a resistor, a capacitor, a thermistor, a diode, an electrostatic discharge prevention element (e.g., a TVS diode), a voltage regulator, or a suitable combination thereof, which perform a function of detecting and blocking an overcurrent, overheating, and/or the like of the battery cell. However, the present disclosure is not limited thereto, and may the electronic components may include various suitable electronic components for detecting abnormal states of the battery, or for storing and/or processing state information. For example, the electronic components may include an EEPROM or a microcontroller unit (MCU) for storing and/or processing battery cell state information. A space may be formed between the electronic components, between the electronic components and the first circuit board 310, and on top of the electronic components. According to an embodiment, a filling resin may be applied to and cured in the space, thereby preventing or substantially preventing an impact from the outside or a penetration of moisture, and improving a mechanical stability of the electronic components and a durability of the protection circuit module 300. For example, the filling resin may include an epoxy resin, a urethane resin, a silicone resin, an acrylic resin, or a suitable combination thereof.

The second circuit board 340 may have a suitable shape extending in the first direction (e.g., the X-axis direction). A surface of the second circuit board 340 that contacts the first circuit board 310 may be connected to the first circuit board 310 by soldering. However, the connection method of the surfaces where the first circuit board 310 and the second circuit board 340 contact each other is not limited thereto, and they may be connected to each other by various suitable connection methods.

The coupling member 350 may couple the first circuit board 310 and the second circuit board 340 to each other. According to an embodiment, at least a portion of the coupling member 350 may be inserted into the indented part 314. The coupling member 350 may be on at least a portion of the indented part 314, and on at least a portion of the second circuit board 340. As a result, the coupling strength between the first circuit board 310 and the second circuit board 340 may be improved.

The coupling member 350 may include a suitable material having a strong adhesive force to improve the coupling strength between the first circuit board 310 and the second circuit board 340. For example, the coupling member 350 may include at least one of an epoxy resin, silicone, polyurethane, polyimide, a UV curable resin, and/or acrylic. As a result, the coupling strength between the first circuit board 310 and the second circuit board 340 may be improved. The coupling member 350 may absorb an external force applied to the first circuit board 310 and the second circuit board 340 to prevent or substantially prevent damage. The coupling member 350 may have a high heat resistance to withstand a high temperatures.

The coupling member 350 may be on at least a portion of the indented part 314, and on at least a portion of the second circuit board 340 through a coating and curing process. The curing process may be a thermosetting or UV curing process, so that the coupling member 350 may be fixed. Curing conditions may be set or determined according to the characteristics of the coupling member 350. For example, the curing conditions may include a curing temperature, a curing time, and the like. As a result, the coupling member 350 may penetrate between the first circuit board 310 and the second circuit board 340, or may be inserted into the indented part 314 and cured, thereby improving the mechanical coupling force of the protection circuit module 300.

FIG. 4 is a plan view illustrating an example of a protection circuit module including an indented part penetrating an end in a second direction, and a coupling member having a width corresponding to a width of the indented part, according to an embodiment of the present disclosure.

FIG. 4 may correspond to a plan view of the part A of FIG. 3 when viewed in the Y-axis direction. In the drawings from FIG. 4 and onwards, mounted components and a sealing part that seals the mounted components of the first circuit board 310 shown in FIG. 3 are omitted for convenience of illustration. The first circuit board 410 and the second circuit board 440 may refer to the boards of the protection circuit module, excluding the components and the sealing parts.

Referring to FIG. 4, at least a portion of the coupling member 450 may be inserted into the indented part 414 of the first circuit board 410. For example, the coupling member 450 may be on at least a portion of the indented part 414 of the first circuit board 410, and on at least a portion of the second circuit board 440. The coupling member 450 may be on an entirety of the indented part 414 of the first circuit board 410, and on a portion of the second circuit board 440.

According to an embodiment, a width w1 of the second circuit board 440 may correspond to a width w2 of the first circuit board 410. With respect to the third direction (e.g., the Z-axis direction), the width w1 of the second circuit board 440 may be the same or substantially the same as the width w2 of the first circuit board 410.

According to an embodiment, with respect to the third direction (e.g., the Z-axis direction), the center of the second circuit board 440 may correspond to the center of the first circuit board 410. As shown in FIG. 4, the center of the width w2 of the first circuit board 410 and the center of the width w1 of the second circuit board 440 may be disposed to correspond to a virtual center line C.

According to an embodiment, the indented part 414 may be formed to penetrate the end 412 of the first circuit board 410 in the second direction (e.g., the Y-axis direction). On a plane including the X-axis and the Z-axis (e.g., in a plan view), the indented part 414 may have a semicircular shape. However, the shape of the indented part 414 is not limited thereto, and the indented part 414 may be formed in various suitable shapes.

According to an embodiment, the indented part 414 may be formed by penetrating the end 412 of the first circuit board 410 using a drill. For example, before the first circuit board 410 is coupled to the second circuit board 440, the indented part 414 penetrating the end 412 of the first circuit board 410 may be formed using a drill. In another embodiment, the indented part 414 may be formed by penetrating the end 412 of the first circuit board 410 using a laser. For example, the indented part 414 may be formed by locally heating the end of the first circuit board 410 by a laser, and removing the heated portion.

According to an embodiment, the first circuit board 410 may include a circuit pattern. The circuit pattern may be designed on the first circuit board 410 with a conductive material, such as copper (Cu), for electrical signals to flow. The circuit pattern may be designed to avoid the portion where the indented part 414 is formed at the end 412 of the first circuit board 410. As a result, the design of the circuit pattern may not be affected by the indented part 414 of the first circuit board 410.

According to an embodiment, the indented part 414 may be formed at the center of the first circuit board 410, with respect to the third direction (e.g., the Z-axis direction) perpendicular to or substantially perpendicular to the first direction (e.g., the X-axis direction) and the second direction (e.g., the Y-axis direction). The center of the indented part 414 may be arranged to correspond to the virtual center line C. However, the position of the indented part 414 is not limited thereto, and the indented part 414 may be formed at various suitable positions of the end 412 of the first circuit board 410.

According to an embodiment, with respect to the third direction (e.g., the Z-axis direction), a length w3 of the indented part 414 may be less than or equal to 50% of the width w2 of the first circuit board 410. The width w2 of the first circuit board 410 may refer to a length of the first circuit board 410 in the third direction (e.g., the Z-axis direction). With respect to the third direction (e.g., the Z-axis direction), the length w3 of the indented part 414 may refer to the width of the indented part 414.

According to an embodiment, with respect to the first direction (e.g., the X-axis direction), a length d1 of the indented part 414 may be less than or equal to 50% of the width w2 of the first circuit board 410. The length d1 of the indented part 414 in the first direction (e.g., the X-axis direction) may refer to a depth of the indented part 414 penetrating the end 412 of the first circuit board 410.

According to an embodiment, the coupling member 450 may have a width that decreases as a distance from the end 412 increases. The width of the coupling member 450 may refer to a length of the coupling member 450 in the third direction (e.g., the Z-axis direction). A maximum width w4 of the coupling member 450 may be equal to or substantially equal to the width w3 of the indented part 414. As a result, the coupling strength between the first circuit board 410 and the second circuit board 440 may be improved. However, the present disclosure is not limited thereto, and the coupling member 450 may have a width that increases or has a constant part as a distance from the end 412 increases.

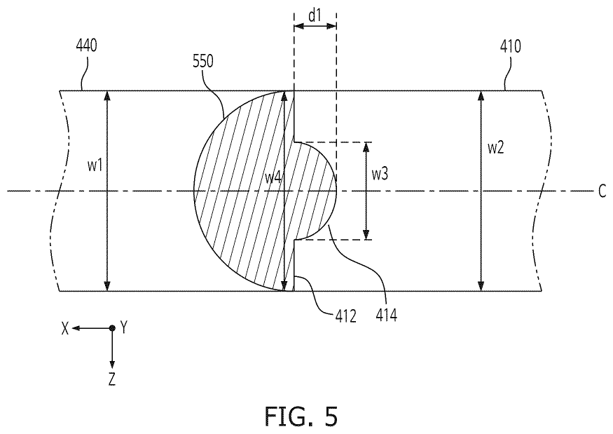

FIG. 5 is a plan view illustrating an example of a protection circuit module including an indented part penetrating an end in a second direction, and a coupling member having a width greater than a width of the indented part, according to an embodiment of the present disclosure.

FIG. 5 may correspond to a plan view of the part A of FIG. 3 when viewed in the Y-axis direction. Hereinafter with reference to FIG. 5, redundant description of the same or substantially the same components as those described above with reference to FIG. 4 may not be repeated.

As shown in FIG. 5, the coupling member 550 may have a width that decreases as a distance from the end 412 increases. According to an embodiment, a maximum width w4 of the coupling member 550 may be greater than the width w3 of the indented part 414. As a result, the coupling strength between the first circuit board 410 and the second circuit board 440 may be improved. However, the present disclosure is not limited thereto, and the coupling member 550 may have a width that increases or has a constant part as a distance from the end 412 increases.

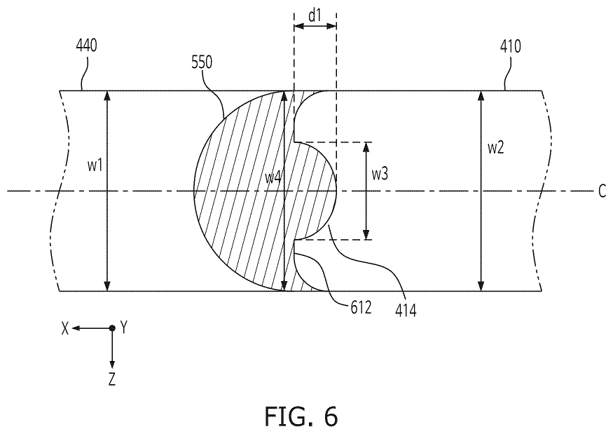

FIG. 6 is a plan view illustrating an example of a protection circuit module including an indented part penetrating an end in a second direction, and an end including a curved surface at a corner, according to an embodiment of the present disclosure. FIG. 6 may correspond to a plan view of the part A of FIG. 3 when viewed in the Y-axis direction. Hereinafter with reference to FIG. 6, redundant description of the same or substantially the same components as those described above with reference to FIGS. 4 and 5 may not be repeated.

Referring to FIG. 6, the end 612 of the first circuit board 410 may include at least one curved surface at a corner thereof. According to an embodiment, the end 612 of the first circuit board 410 may include a curved surface at each corner thereof. The corners of the end 612 may refer to both ends (e.g., opposite ends) in the third direction (e.g., the Z-axis direction). At least a portion of the coupling member 550 may be on the corners of the end 612. As a result, the coupling strength between the first circuit board 410 and the second circuit board 440 may be improved.

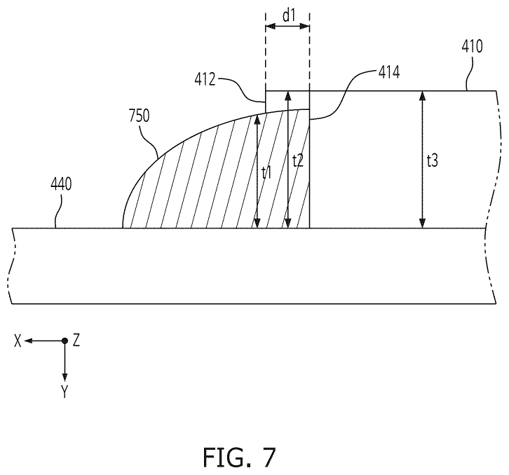

FIG. 7 is a side view illustrating an example of a protection circuit module including an indented part penetrating an end in a second direction, according to an embodiment of the present disclosure.

FIG. 7 may correspond to a side view of a cross-section cut by the virtual center line C in FIGS. 4 to 6 when viewed in the Z-axis direction. Hereinafter with reference to FIG. 7, redundant description of the same or substantially the same components as those described above with reference to FIGS. 4 to 6 may not be repeated.

Referring to FIG. 7, with respect to the second direction (e.g., the Y-axis direction), a length t2 of the indented part 414 may be equal to or substantially equal to a thickness t3 of the first circuit board 410. The length t2 of the indented part 414 may refer to the thickness of the indented part 414 in the second direction (e.g., the Y-axis direction).

As shown in FIG. 7, the coupling member 750 may have a thickness that decreases as a distance from the indented part 414 increases. The thickness of the coupling member 750 may be variously modified according to the designed coupling force of the first circuit board 410 and the second circuit board 440. According to an embodiment, a maximum thickness t1 of the coupling member 750 may be less than or equal to the thickness t2 of the indented part 414. In other words, the top end of the coupling member 750 may be less than or equal to the height of the top end of the indented part 414.

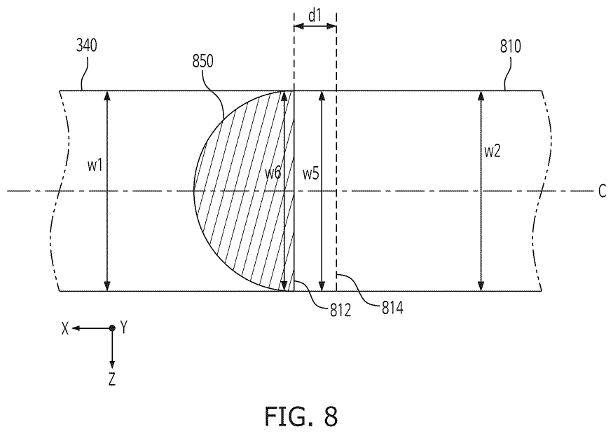

FIG. 8 is a plan view illustrating an example of a protection circuit module including an indented part penetrating an end with respect to a third direction, according to an embodiment of the present disclosure. Hereinafter with reference to FIG. 8, redundant description of the same or substantially the same components as those described above with reference to FIGS. 4 to 7 may not be repeated.

Referring to FIG. 8, with respect to the third direction (e.g., the Z-axis direction), a length w5 of the indented part 814 may be equal to or substantially equal to the width w2 of the first circuit board 810. With respect to the third direction (e.g., the Z-axis direction), the length w5 of the indented part 814 may be referred to as the width of the indented part 814.

As shown in FIG. 8, the coupling member 850 may have a width that decreases as a distance from the end 812 increases. The width of the coupling member 850 may be variously modified according to the designed coupling force of the first circuit board 810 and the second circuit board 840. According to an embodiment, a maximum width w6 of the coupling member 850 may be equal to or substantially equal to the width w5 of the indented part 814. As another example, the maximum width w6 of the coupling member 850 may be less than the width w5 of the indented part 814. However, the present disclosure is not limited thereto, and the coupling member 850 may have a width that increases or has a constant part as a distance from the end 812 increases.

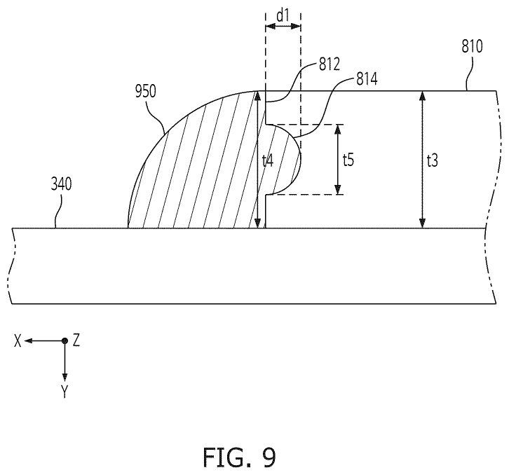

FIG. 9 is a side view illustrating an example of a protection circuit module including an indented part penetrating an end with respect to a third direction, and a coupling member having a top end higher than a top end of the indented part, according to an embodiment of the present disclosure. FIG. 9 may correspond to a side view of a cross-section cut by the virtual center line C in FIG. 8 when viewed in the Z-axis direction. Hereinafter with reference to FIG. 9, redundant description of the same or substantially the same components as those described above with reference to FIGS. 4 to 8 may not be repeated.

Referring to FIG. 9, at least a portion of the coupling member 950 may be inserted into the indented part 814 of the first circuit board 810. The coupling member 950 may be on at least a portion of the indented part 814 of the first circuit board 810, and on at least a portion of the second circuit board 840. The coupling member 950 may be on an entirety of the indented part 814 of the first circuit board 810, and on a portion of the second circuit board 840.

According to an embodiment, the indented part 814 may be formed to penetrate the end 812 of the first circuit board 810 in the third direction (e.g., the Z-axis direction). On a plane including the X-axis and the Y-axis, the indented part 814 may have a semicircular shape.

According to an embodiment, the indented part 814 may be formed at a center of the first circuit board 810 with respect to the second direction (e.g., the Y-axis direction). However, the position of the indented part 814 is not limited thereto, and the indented part 814 may be formed at various suitable positions of the end 812 of the first circuit board 810.

According to an embodiment, with respect to the second direction (e.g., the Y-axis direction), a length t5 of the indented part 814 may be less than or equal to 50% of the thickness t3 of the first circuit board 810. The thickness t3 of the first circuit board 810 may refer to the length of the first circuit board 810 in the second direction (e.g., the Y-axis direction). With respect to the second direction (e.g., the Y-axis direction), the length t5 of the indented part 814 may be referred to as the thickness of the indented part 814.

According to an embodiment, with respect to the first direction (e.g., the X-axis direction), the length d1 of the indented part 814 may be less than or equal to 50% of the thickness t3 of the first circuit board 810. With respect to the first direction (e.g., the X-axis direction), the length d1 of the indented part 814 may be referred to as the depth of the indented part 814.

According to an embodiment, the coupling member 950 may have a thickness that decreases as a distance from the end 812 increases. A maximum thickness t4 of the coupling member 950 may be the same or substantially the same as, or may be less than, the thickness t3 of the first circuit board 810. The top end of the coupling member 950 may be higher than the top end of the indented part 814. The top end of the coupling member 950 may have a height less than or equal to the height of the top end of the first circuit board 810.

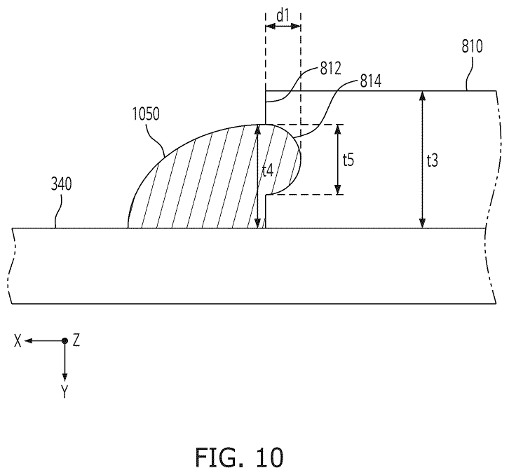

FIG. 10 is a side view illustrating an example of a protection circuit module including an indented part penetrating an end with respect to a third direction, and a coupling member having a top end corresponding to a top end of the indented part, according to an embodiment of the present disclosure. FIG. 10 may correspond to a side view of a cross-section cut by the virtual center line C in FIG. 8 when viewed in the Z-axis direction. Hereinafter with reference to FIG. 10, redundant description of the same or substantially the same components as those described above with reference to FIGS. 4 to 9 may not be repeated.

As shown in FIG. 10, the coupling member 1050 may have a thickness that decreases from a maximum thickness t4 as a distance from the end 812 increases. The thickness of the coupling member 1050 may be variously modified according to the designed coupling force of the first circuit board 810 and the second circuit board 840. According to an embodiment, the top end of the coupling member 1050 may have a height equal to or substantially equal to the height of the top end of the indented part 814. The top end of the indented part 814 may refer to the top end of the indented part 814 in the second direction (e.g., the Y-axis direction).

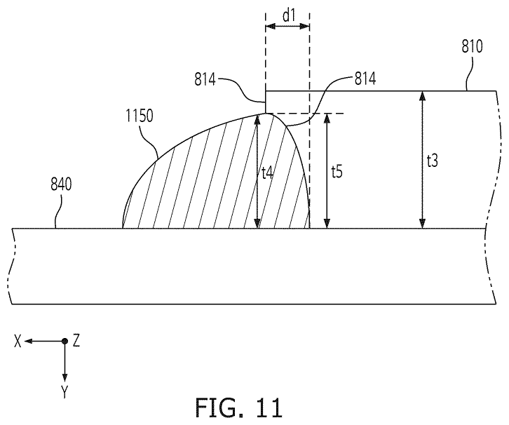

FIG. 11 is a side view illustrating an example of a protection circuit module including an indented part penetrating an end with respect to a third direction, and a coupling member having a top end corresponding to a top end of the indented part, according to an embodiment of the present disclosure. FIG. 11 may correspond to a side view of a cross-section cut by the virtual center line C in FIG. 8 when viewed in the Z-axis direction. Hereinafter with reference to FIG. 11, redundant description of the same or substantially the same components as those described above with reference to FIGS. 4 to 10 may not be repeated.

Referring to FIG. 11, the indented part 814 may be formed from the center to the bottom of the first circuit board 810, with respect to the second direction (e.g., the Y-axis direction). Accordingly, the indented part 814 may have a shape covering at least a portion of the coupling member 1150.

As shown in FIG. 11, the coupling member 1150 may have a thickness that decreases from a maximum thickness t4 as a distance from the end 812 increases. The thickness of the coupling member 1150 may be variously modified according to the designed coupling force of the first circuit board 810 and the second circuit board 840. According to an embodiment, the top end of the coupling member 1150 may have a height equal to or substantially equal to the height of the top end of the indented part 814. The top end of the indented part 814 may refer to the top end of the indented part 814 in the second direction (e.g., the Y-axis direction).

Although the present disclosure has been described above with respect to embodiments thereof, the present disclosure is not limited thereto. Various modifications and variations can be made thereto by those skilled in the art within the spirit of the present disclosure and the equivalent scope of the appended claims.

What is claimed is:

1. A protection circuit module comprising:
a first circuit board electrically connected to a battery cell, and extending in a first direction;
a second circuit board electrically connected to the first circuit board; and
a coupling member coupling the first circuit board and the second circuit board to each other,
wherein the first circuit board comprises an indented part at an end overlapping with the second circuit board in a second direction crossing the first direction, and at least a portion of the coupling member is inserted into the indented part.

2. The protection circuit module as claimed in claim 1, wherein the indented part has a concave shape in an inner direction of the first circuit board on a surface of the end facing the first direction.

3. The protection circuit module as claimed in claim 1, wherein the indented part penetrates the end of the first circuit board in the second direction.

4. The protection circuit module as claimed in claim 3, wherein the indented part is located at a center of the first circuit board with respect to a third direction crossing the first direction and the second direction.

5. The protection circuit module as claimed in claim 3, wherein a length of the indented part is less than or equal to 50% of a width of the first circuit board with respect to a third direction crossing the first direction and the second direction.

6. The protection circuit module as claimed in claim 3, wherein a length of the indented part is less than or equal to 50% of a width of the first circuit board with respect to the first direction.

7. The protection circuit module as claimed in claim 3, wherein the coupling member has a width that decreases as a distance from the end increases, and a maximum width of the coupling member is greater than or equal to a width of the indented part.

8. The protection circuit module as claimed in claim 1, wherein the indented part penetrates the end of the first circuit board in a third direction crossing the first direction and the second direction.

9. The protection circuit module as claimed in claim 8, wherein the indented part is located at a center of the first circuit board with respect to the second direction.

10. The protection circuit module as claimed in claim 8, wherein a length of the indented part is less than or equal to 50% of a thickness of the first circuit board with respect to the second direction.

11. The protection circuit module as claimed in claim 8, wherein a length of the indented part is less than or equal to 50% of a thickness of the first circuit board with respect to the first direction.

12. The protection circuit module as claimed in claim 8, wherein the coupling member has a thickness that decreases as a distance from the end increases, and a top end of the coupling member is higher than or at a same height as that of a top end of the indented part.

13. The protection circuit module as claimed in claim 1, wherein the coupling member comprises at least one of an epoxy resin, silicone, polyurethane, or acrylic.

14. The protection circuit module as claimed in claim 1, wherein a width of the second circuit board corresponds to a width of the first circuit board.

15. The protection circuit module as claimed in claim 14, wherein a center of the second circuit board corresponds to a center of the first circuit board with respect to a third direction crossing the first direction and the second direction.

16. A battery assembly comprising:
a battery cell comprising an electrode tab; and
a protection circuit module electrically connected to the electrode tab,
wherein the protection circuit module comprises:
a first circuit board electrically connected to the battery cell, and extending in a first direction;
a second circuit board electrically connected to the first circuit board; and
a coupling member coupling the first circuit board and the second circuit board to each other,
wherein the first circuit board comprises an indented part at an end overlapping with the second circuit board in a second direction crossing the first direction, and at least a portion of the coupling member is inserted into the indented part.

17. The battery assembly as claimed in claim 16, wherein the indented part has a concave shape in an inner direction of the first circuit board on a surface of the end facing the first direction.

18. The battery assembly as claimed in claim 16, wherein the indented part penetrates the end of the first circuit board in the second direction.

19. The battery assembly as claimed in claim 16, wherein the indented part penetrates the end of the first circuit board in a third direction crossing the second direction.

20. The battery assembly as claimed in claim 16, wherein the coupling member comprises at least one of an epoxy resin, silicone, polyurethane, or acrylic.
